(19) United States
(12) Patent Application Publication
(10) Pub. No.: US 2025/0356943 A1
(43) Pub. Date: Nov. 20, 2025

(54) MANAGING MEMORY BACKUP POWER MODULES

(71) Applicant: International Business Machines Corporation, Armonk, NY (US)

(72) Inventors: Matthew G. Borlick, Tucson, AZ (US); Micah Robison, Tucson, AZ (US); John Charles Elliott, Tucson, AZ (US); Lokesh Mohan Gupta, Tucson, AZ (US)

(21) Appl. No.: 18/665,353

(22) Filed: May 15, 2024

(51) Int. Cl. G11C 29/56; G11C 5/14

(52) U.S. Cl. CPC G11C 29/56016; G11C 5/141; G11C 29/56004; G11C 2029/5604

(57) ABSTRACT

A computer-implemented method, according to one approach, includes: in response to a system detecting an initial microcode load, determining whether memory in the system was disarmed during manufacture. The memory in the system is connected to backup power modules. The computer-implemented method also includes monitoring for concurrent code loads in response to determining that the memory was disarmed during manufacture. Moreover, in response to detecting a concurrent code load, the energy levels of the backup power modules are tested. A warning is further issued in response to determining the energy levels of one or more of the backup power modules are outside a predetermined range. Other systems, computer-implemented methods, and computer program products are described in additional approaches.

### BACKGROUND

The present invention relates to non-volatile memory, and more specifically, this invention relates to inspecting backup power modules.

Non-volatile memory is memory that retains its contents even when electrical power is removed. For example, the supply power for memory is cut in unexpected power losses, system crashes, and even normal shutdowns. This improves data retention in comparison to volatile memory, which is not able to retain data following a power loss.

However, many “non-volatile” products use volatile memory during normal operation and use an on-board backup power source to dump the contents of the volatile memory into non-volatile memory. This is because, despite its power limitations, volatile memory is typically faster than non-volatile memory. Volatile memory is also byte-addressable, and can be written to arbitrarily, without concerns about wear and memory lifespan. The battery backup thereby serves an important role in ensuring data retention.

While attempts have been made to ensure battery backups are adequately charged, conventional products have still experienced performance issues. For instance, manufacturers often ship memory in a configuration where the battery backups are in an active state (e.g., charge is being lost at least incrementally). As a result, the memory operates at a client location with insufficient energy reserves to ensure that data is retained in response to an unexpected loss of power.

### SUMMARY

A computer-implemented method (CIM), according to one approach, includes: in response to a system detecting an initial microcode load, determining whether memory in the system was disarmed during manufacture. The memory in the system is connected to backup power modules. The CIM also includes monitoring for concurrent code loads in response to determining that the memory was disarmed during manufacture. Moreover, in response to detecting a concurrent code load, the energy levels of the backup power modules are tested. A warning is further issued in response to determining the energy levels of one or more of the backup power modules are outside a predetermined range.

A computer program product (CPP), according to another approach, includes: a set of one or more computer-readable storage media. The CPP also includes program instructions that are collectively stored in the set of one or more storage media, and for causing a processor set to perform the foregoing CIM.

A computer system (CS), according to yet another approach, includes: a processor set, and a set of one or more computer-readable storage media. The CS also includes program instructions that are collectively stored in the set of one or more storage media, and for causing the processor set to perform the foregoing CIM.

Other aspects and implementations of the present invention will become apparent from the following detailed description, which, when taken in conjunction with the drawings, illustrate by way of example the principles of the invention.

### BRIEF DESCRIPTION OF THE DRAWINGS

FIG. 1 is a diagram of a computing environment, in accordance with one approach.

FIG. 2 is a representational view of a distributed system, in accordance with one approach.

FIG. 3A is a flowchart of a method, in accordance with one approach.

FIG. 3B is a flowchart of sub-operations for one of the operations in the method of FIG. 3A, in accordance with one approach.

FIG. 4A is a flowchart of a method, in accordance with one approach.

FIG. 4B is a flowchart of sub-operations for one of the operations in the method of FIG. 4A, in accordance with one approach.

FIG. 5 is a flowchart of a method, in accordance with one approach.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The following description discloses several preferred approaches of systems, methods and computer program products for managing and testing backup power modules in a number of different settings for performance related issues. In other words, approaches herein are able to monitor backup power modules in order to ensure data in memory is protected against sudden loss of power. Approaches herein are thereby able provide an effective way of maintaining data integrity even in situations where backup power modules are compromised, e.g., as the result of manufacturing and/or shipping issues, as will be described in further detail below.

In one general approach, a CIM includes: in response to a system detecting an initial microcode load, determining whether memory in the system was disarmed during manufacture. The memory in the system is connected to backup power modules. The CIM also includes monitoring for concurrent code loads in response to determining that the memory was disarmed during manufacture. Moreover, in response to detecting a concurrent code load, the energy levels of the backup power modules are tested. A warning is further issued in response to determining the energy levels of one or more of the backup power modules are outside a predetermined range.

In another general approach, a CPP includes: a set of one or more computer-readable storage media. The CPP also includes program instructions that are collectively stored in the set of one or more storage media, and for causing a processor set to perform the foregoing CIM.

In yet another general approach, a CS includes: a processor set, and a set of one or more computer-readable storage media. The CS also includes program instructions that are collectively stored in the set of one or more storage media, and for causing the processor set to perform the foregoing CIM.

Various aspects of the present disclosure are described by narrative text, flowcharts, block diagrams of computer systems and/or block diagrams of the machine logic included in CPP approaches. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product approach (“CPP approach” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as improved data retention code at block 150 for managing and testing backup power modules in a number of different settings for performance related issues. In other words, monitoring backup power modules helps ensure data in memory is protected against sudden loss of power. Approaches herein are thereby able provide an effective way of maintaining data integrity even in situations where backup power modules are compromised as the result of manufacturing and/or shipping issues, e.g., as will be described in further detail below.

In addition to block 150, computing environment 100 includes, for example, computer 101, wide area network (WAN) 102, end user device (EUD) 103, remote server 104, public cloud 105, and private cloud 106. In this approach, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

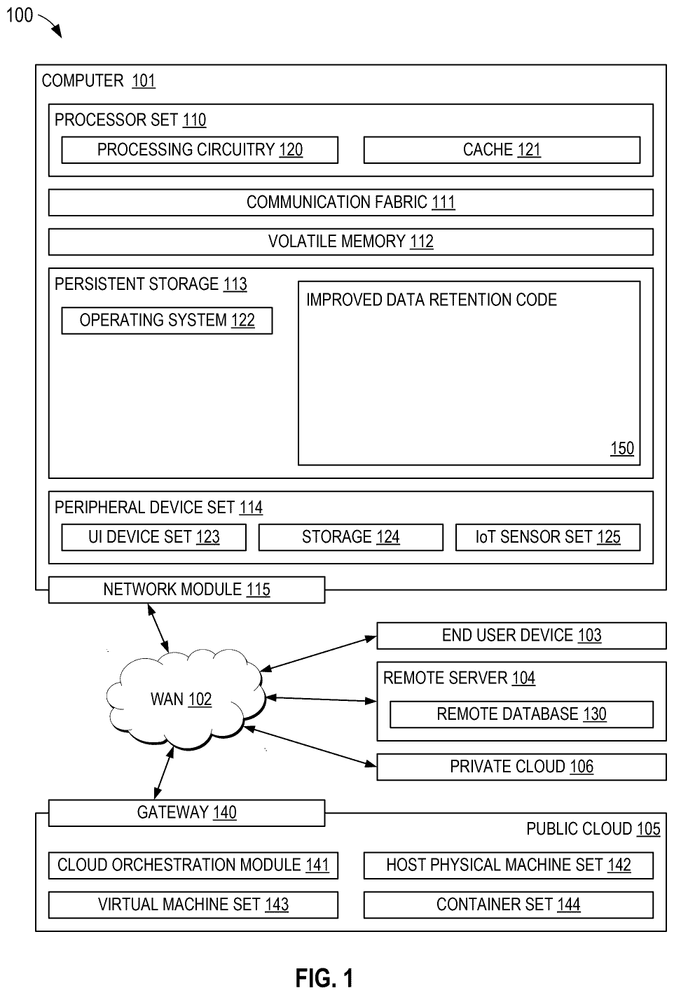

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various approaches, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some approaches, storage 124 may take the form of a quantum computing storage device for storing data in the form of qubits. In approaches where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some approaches, network control functions and network forwarding functions of network module 115 are performed on the same physical hardware device. In other approaches (for example, approaches that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some approaches, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some approaches, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other approaches a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this approach, public cloud 105 and private cloud 106 are both part of a larger hybrid cloud.

CLOUD COMPUTING SERVICES AND/OR MICROSERVICES (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some approaches, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

In some aspects, a system according to various approaches may include a processor and logic integrated with and/or executable by the processor, the logic being configured to perform one or more of the process steps recited herein. The processor may be of any configuration as described herein, such as a discrete processor or a processing circuit that includes many components such as processing hardware, memory, I/O interfaces, etc. By integrated with, what is meant is that the processor has logic embedded therewith as hardware logic, such as an application specific integrated circuit (ASIC), a FPGA, etc. By executable by the processor, what is meant is that the logic is hardware logic; software logic such as firmware, part of an operating system, part of an application program; etc., or some combination of hardware and software logic that is accessible by the processor and configured to cause the processor to perform some functionality upon execution by the processor. Software logic may be stored on local and/or remote memory of any memory type, as known in the art. Any processor known in the art may be used, such as a software processor module and/or a hardware processor such as an ASIC, a FPGA, a central processing unit (CPU), an integrated circuit (IC), a graphics processing unit (GPU), etc.

Of course, this logic may be implemented as a method on any device and/or system or as a computer program product, according to various approaches.

As noted above, non-volatile memory is memory that retains its contents even when electrical power is removed. For example, the supply power for memory is cut in unexpected power losses, system crashes, and even normal shutdowns. This improves data retention in comparison to volatile memory, which is not able to retain data following a power loss.

However, many “non-volatile” products use volatile memory during normal operation and use an on-board backup power source to dump the contents of the volatile memory into non-volatile memory. This is because, despite its power limitations, volatile memory is typically faster than non-volatile memory. Volatile memory is also byte-addressable, and can be written to arbitrarily, without concerns about wear and memory lifespan. The battery backup thereby serves an important role in ensuring data retention.

While attempts have been made to ensure battery backups are adequately charged, conventional products have still suffered performance issues. For instance, manufacturers often ship memory in a configuration where the battery backups are in an active state (e.g., charge is being lost at least incrementally). As a result, the memory operates at a client location with insufficient energy reserves to ensure that data is retained in response to an unexpected loss of power.

In sharp contrast, approaches herein are desirably able to ensure that memory components are fully disarmed during a controlled shutdown that occurs prior to shipment. This ensures memory arrives at client locations as intended, e.g., with sufficiently charged battery backups. Moreover, the relative health of the battery backups are evaluated over time to ensure the memory operates successfully, e.g., even in response to an unexpected power loss. For instance, the energy levels of battery backups may be tested during concurrent code loads. Similarly, energy levels may be inspected during periods of low input/output (I/O) traffic, e.g., as will be described in further detail below.

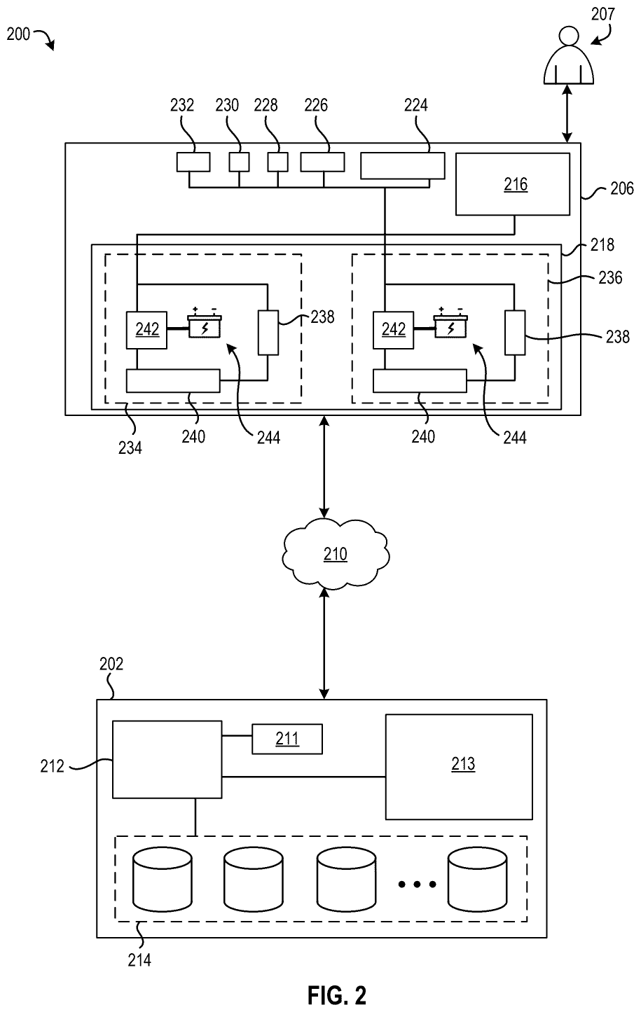

Looking now to FIG. 2, a system 200 having a distributed architecture is illustrated in accordance with one approach. As an option, the present system 200 may be implemented in conjunction with features from any other approach listed herein, such as those described with reference to the other FIGS., such as FIG. 1. However, such system 200 and others presented herein may be used in various applications and/or in permutations which may or may not be specifically described in the illustrative approaches or implementations listed herein. Further, the system 200 presented herein may be used in any desired environment. Thus FIG. 2 (and the other FIGS.) may be deemed to include any possible permutation.

As shown, the system 200 includes a central server 202 that is connected to an edge node 206 accessible to an administrator 207. It should be noted that the terms “administrator” and “user” as stated herein are in no way intended to be limiting. For instance, while users and administrators may be described as being individuals in various implementations herein, a user and/or an administrator may be an application, an organization, a preset process, etc. The use of “data,” “datasets,” “metadata,” and “information” herein are in no way intended to be limiting either, and may include any desired type of details, e.g., depending on the type of operating system implemented on the edge node 206 and/or central server 202.

The central server 202 and edge node 206 are each connected to a network 210, and may thereby be positioned in different geographical locations. The network 210 may be of any type, e.g., depending on the desired approach. For instance, in some approaches the network 210 is a WAN, e.g., such as the Internet. However, an illustrative list of other network types which network 210 may implement includes, but is not limited to, a LAN, a PSTN, a SAN, an internal telephone network, etc. As a result, any desired information, data, commands, instructions, responses, requests, etc. may be sent between edge node 206 and central server 202, regardless of the amount of separation which exists therebetween, e.g., despite being positioned at different geographical locations. According to some approaches, the central server 202 is a remote cloud server that is connected to (e.g., may be accessed by) edge node 206.

The central server 202 includes a large (e.g., robust) processor 212 coupled to a cache 211, an AI module 213, and a data storage array 214 having a relatively high storage capacity. The AI module 213 may include any desired number and/or type of AI-based models, e.g., such as machine learning models, deep learning models, neural networks, etc. In preferred approaches, the AI module 213 includes models that have been trained to evaluate various conditions at the edge node 206 and determine whether the components therein are properly configured. For instance, the AI based models may be configured to detect anomalies in the relative health of various backup power modules coupled to respective volatile memory components, and identify how to address the anomalies to maintain performance. It follows that AI module 213 and/or processor 212 may be used to perform one or more of the operations in method 300 below for managing and testing backup power modules in a number of different settings for performance related issues, e.g., as will be described in further detail below.

Looking to the edge node 206, a central processor 216 is coupled to memory 218. The processor 216 may receive inputs from, and interface with, administrator 207. For instance, the administrator 207 may input information using one or more of: a display screen 224, keys of a computer keyboard 226, a computer mouse 228, a microphone 230, and a camera 232. The processor 216 may thereby be configured to receive inputs (e.g., text, sounds, images, motion data, etc.) from any of these components as entered by the administrator 207. These inputs typically correspond to information presented on the display screen 224 while the entries were received. Moreover, the inputs received from the keyboard 226 and computer mouse 228 may impact the information shown on display screen 224, data stored in memory 218, information collected from the microphone 230 and/or camera 232, status of an operating system being implemented by processor 216, etc.

Memory 218 further shown as including a first Central Electronic Complex (CEC) 234 in addition to a second CEC 236. Each of the CECs 234, 236 include components (e.g., hardware and/or software) that are configured to define a mainframe. In other words, each of the CECs 234, 236 may be used to create and maintain an environment in software that may be accessed to perform various operations (e.g., I/Os). While both CECs 234, 236 are depicted as having the same configuration, this is in no way intended to be limiting. For example, different CECs may include different types of memory depending on the approach.

In the present approach, each CEC 234, 236 is depicted as including a processor 238. The processors 238 are connected to non-volatile memory 240 as well as volatile memory 242. Each of the volatile memory 242 are further connected to a backup power module 244 that is preferably configured to store and supply a sufficient amount of electrical energy to power the volatile memory 242 in the absence of a main energy source, e.g., as a result of an unplanned power outage. As previously mentioned, in some approaches even “non-volatile” memory uses volatile memory during normal operation, and an on-board backup power source to dump the contents of the volatile memory into non-volatile memory. Thus, despite the power-based limitations associated with volatile memory, approaches herein allow for the system to benefit from the faster performance, while also being protected from experiencing data loss.

Approaches herein also manage the backup power modules 244 by ensuring each is sufficiently configured to support the volatile memory 242 in a number of different settings. In other words, approaches herein are desirably able to monitor the backup power modules 244 in order to ensure data in memory is protected against a sudden loss of power. Approaches herein are thereby able provide an effective way of maintaining data integrity even in situations where one or more of the backup power modules 244 are compromised.

Approaches herein are also desirably able to ensure that memory components are fully disarmed during a controlled shutdown that occurs prior to shipment. This confirms memory arrives at client locations as intended, e.g., with sufficiently charged backup power modules. Moreover, the relative health of the backup power modules are evaluated over time to ensure the memory operates successfully, e.g., even in response to an unexpected power loss. By strategically timing the testing performed on the backup power modules, approaches herein are able to monitor the backup power modules without impacting throughput of the system. For instance, the energy levels of backup power modules may be tested during concurrent code loads. Similarly, energy levels may be inspected during periods of low input/output (I/O) traffic, e.g., as will be described in further detail below.

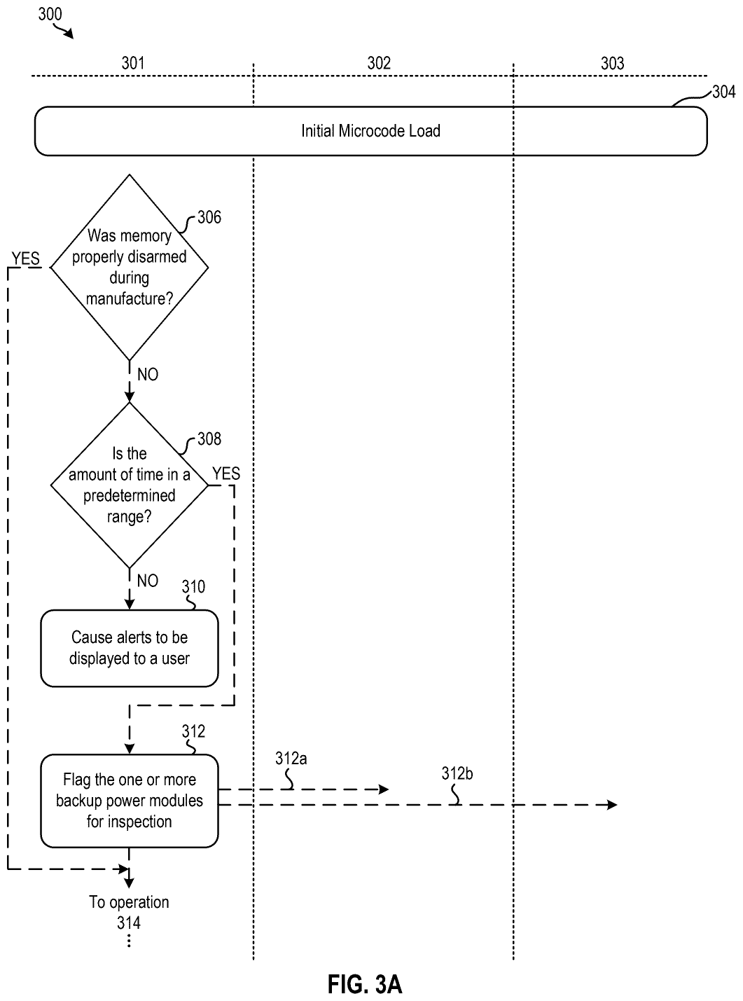

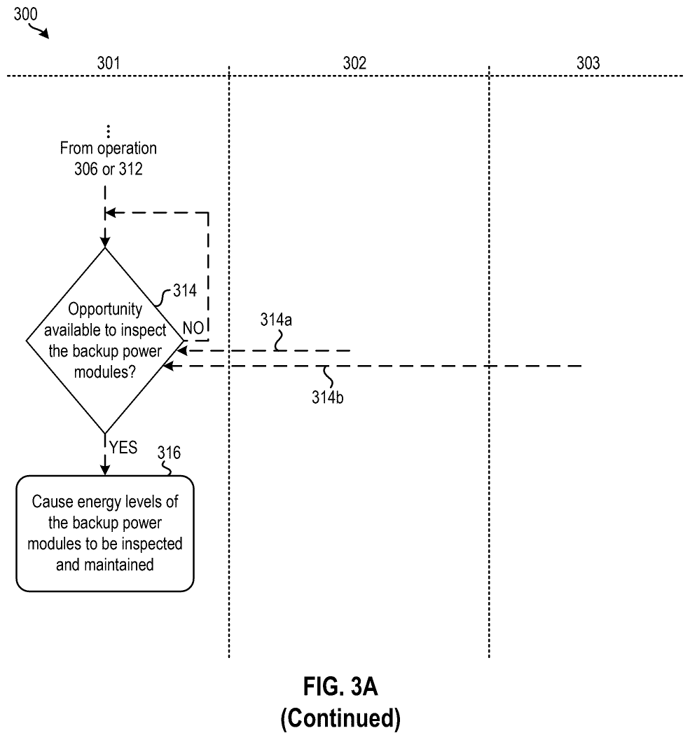

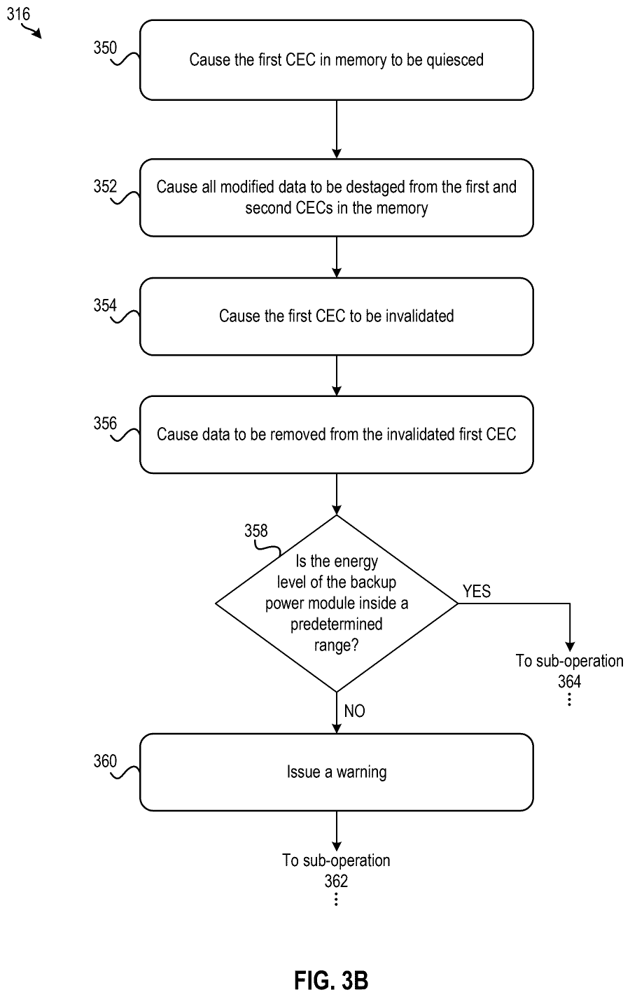

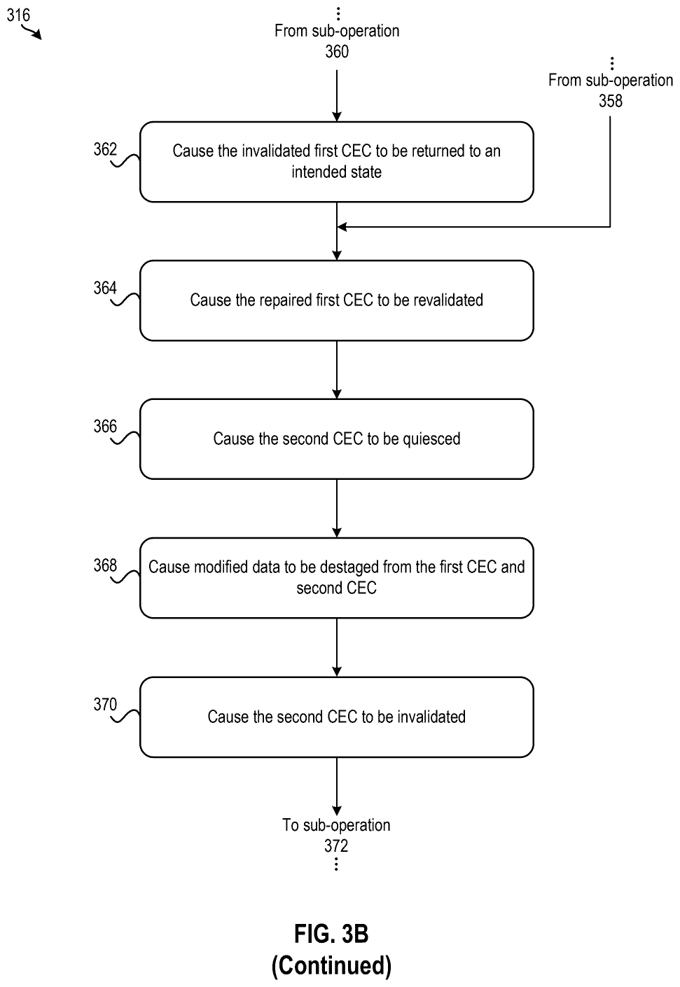

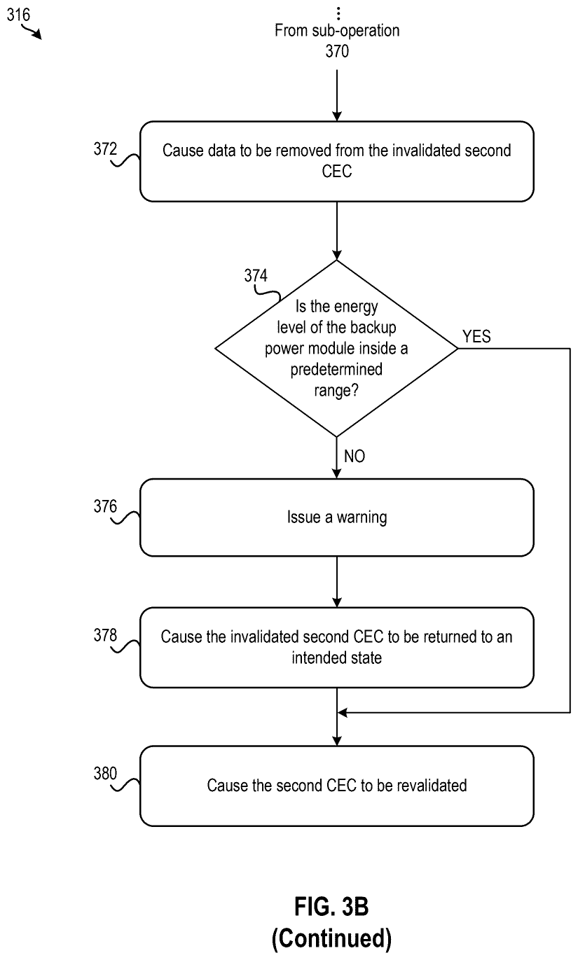

Looking now to FIG. 3A, a flowchart of a computer-implemented-method 300 for managing and testing backup power modules in a number of different settings for performance related issues is illustrated in accordance with one approach. In other words, method 300 includes monitoring backup power modules in order to ensure data in memory is protected against a sudden loss of power. Approaches herein are thereby able provide an effective way of maintaining data integrity even in situations where backup power modules are compromised, e.g., as the result of manufacturing and/or shipping issues.

The method 300 may be performed in accordance with the present invention in any of the environments depicted in FIGS. 1-2, among others, in various approaches. Of course, more or less operations than those specifically described in FIG. 3A may be included in method 300, as would be understood by one of skill in the art upon reading the present descriptions. Each of the steps of the method 300 may be performed by any suitable component of the operating environment. For example, the nodes 301, 302, 303 shown in the flowchart of method 300 may correspond to one or more processors positioned at a different location in a distributed system. Moreover, each of the one or more processors are preferably configured to communicate with each other.

In various approaches, the method 300 may be partially or entirely performed by a controller, a processor, etc., or some other device having one or more processors therein. The processor, e.g., processing circuit(s), chip(s), and/or module(s) implemented in hardware and/or software, and preferably having at least one hardware component may be utilized in any device to perform one or more steps of the method 300. Illustrative processors include, but are not limited to, a central processing unit (CPU), an application specific integrated circuit (ASIC), a field programmable gate array (FPGA), etc., combinations thereof, or any other suitable computing device known in the art.

As mentioned above, FIG. 3A includes different nodes 301, 302, 303, each of which represent one or more processors, controllers, computer, etc., positioned at a different location in a distributed system. For example, in some approaches one or more of the operations in method 300 may involve one or more CECs in memory at an edge node that are further connected to a central server as part of a larger distributed system. Accordingly, node 301 may include one or more processors and/or AI based models which are located at a central server of a distributed system (e.g., see processor 212 and/or AI module 213 of FIG. 2 above). Node 302 may include one or more processors which are located in a first CEC at an edge node of the distributed system (e.g., see processor 238 in first CEC 234 of FIG. 2). Moreover, node 303 may include one or more processors which are located in a second CEC at the edge node of the distributed system (e.g., see processor 238 in second CEC 236 of FIG. 2).

According to another example, operations in method 300 may be performed at an edge node having one or more CECs therein. Node 301 may thereby include one or more central processors at an edge node location (e.g., see processor 216 of FIG. 2 above), while node 302 includes one or more processors in a first CEC at the edge node (e.g., see processor 238 in first CEC 234 of FIG. 2). Moreover, node 303 may include one or more processors in a second CEC at the edge node (e.g., see processor 238 in second CEC 236 of FIG. 2).

Accordingly, commands, code, data, metadata outlining code updates, etc. may be sent between the nodes 301, 302 depending on the approach. It should also be noted that the various processes included in method 300 are in no way intended to be limiting, e.g., as would be appreciated by one skilled in the art after reading the present description. For instance, data sent from node 302 to node 301 may be prefaced by a request sent from node 301 to node 302 in some approaches. It should also be noted that in some approaches, the operations of method 300 may be performed in the closed system itself. Accordingly, one or more of the following approaches may be implemented by a processor in a closed system, e.g., as would be appreciated by one skilled in the art after reading the present description.

Looking to FIG. 3A, operation 304 includes detecting an initial microcode load. In other words, method 300 may be initiated in response to a system experiencing an initial microcode load. While operation 304 is shown as extending across each of nodes 301, 302, 303, this is in no way intended to be limiting. For example, node 301 may be located at a central server that is connected to the CECs at nodes 302 and 303 respectively. In this example, an initial microcode load may only be experienced across nodes 302 and 303, while one or more notifications may be sent to node 301.

In response to the initial microcode load at operation 304, method 300 advances to operation 306. There, operation 306 includes determining whether memory in the system was properly disarmed during manufacture. In other words, operation 306 includes determining whether memory in the system that is connected to backup power modules was properly disarmed at the end of a controlled shutdown during manufacture of the memory. As noted above, approaches herein are desirably able to ensure that memory components have been fully disarmed during a controlled shutdown that occurs prior to shipment. This ensures memory implemented at client locations is configured as intended, e.g., with sufficiently charged battery backups. According to an example, the memory being evaluated in operation 306 includes at least one non-volatile dual in-line memory module (NVDIMM). However, any number and/or type(s) of memory which would be apparent to one skilled in the art after reading the present description may be manufactured and/or evaluated as described in the various approaches herein.

With continued reference to FIG. 3A, it follows that in response to a system experiencing an initial microcode load at a client location, operation 306 again includes determining whether the physical components in memory were each disarmed at the end of a controlled shutdown during manufacture of the memory and before being stored and/or shipped to a client. It should also be noted that while operation 306 is shown as being performed at node 301, it may be based on information received from the CEC at node 302 and/or CEC at node 303. For example, the status of the memory (e.g., whether or not the memory was disarmed) at the end of a controlled shutdown during manufacture may be determined in some approaches using information stored in memory before the controlled shutdown. In some approaches, the controlled shutdown may involve storing a snapshot of each memory component and the state it was in at the point of the controlled shutdown. Moreover, the snapshots and/or any other information corresponding to the memory components may be stored at a central location.

In situations where it is determined that memory was not disarmed at the end of a controlled shutdown during manufacture, the memory and components therein are preferably evaluated further to determine their status. For instance, memory that remains active after a controlled shutdown may continue to draw power, thereby causing backup power modules to be at least partially depleted at the point of initial microcode load. To avoid situations where backup power modules become fully and unexpectedly depleted, the components are evaluated further. In some approaches, a result outlining whether memory was properly disarmed at the end of manufacture may be displayed to a user, e.g., on a display screen, transmitted to a client's mobile device, uploaded to a publicly and/or privately available location (e.g., public or private web address, server location, etc.), etc.

For instance, method 300 advances from operation 306 to operation 308 in response to determining that the memory was not disarmed at the end of a controlled shutdown during manufacture. There, operation 308 includes determining whether the amount of time between (i) the controlled shutdown during manufacture, and (ii) the system experiencing the initial microcode load, is in a predetermined range. In other words, operation 308 includes determining whether an undesirably long amount of time separates the controlled shutdown of the memory during manufacture, and the initial microcode load. The predetermined range may be set by a user (e.g., client), industry standards, application parameters, power draw during intended shutdown, storage capacity of the backup power modules, etc.

Method 300 advances to operation 310 in response to determining that the amount of time that has passed is not in the predetermined range. In other words, method 300 advances to operation 310 in response to determining that an undesirable amount of time has passed since the backup power module(s) were intended to have been shut down (e.g., taken offline). There, operation 310 includes causing one or more alerts to be displayed to a user (e.g., client). The alerts preferably convey that the backup power modules should be tested before being trusted to improve data retention. Moreover, the alert may be sent wirelessly to a user's device (e.g., mobile device, laptop computer, desktop computer, etc.) over one or more networks. It should also be noted that “in a predetermined range” is in no way intended to be limiting. Rather than determining whether a value is in a predetermined range, equivalent determinations may be made, e.g., as to whether a value is above a threshold, whether a value is outside a predetermined range, whether an absolute value is above a threshold, whether a value is below a threshold, etc., depending on the desired approach.

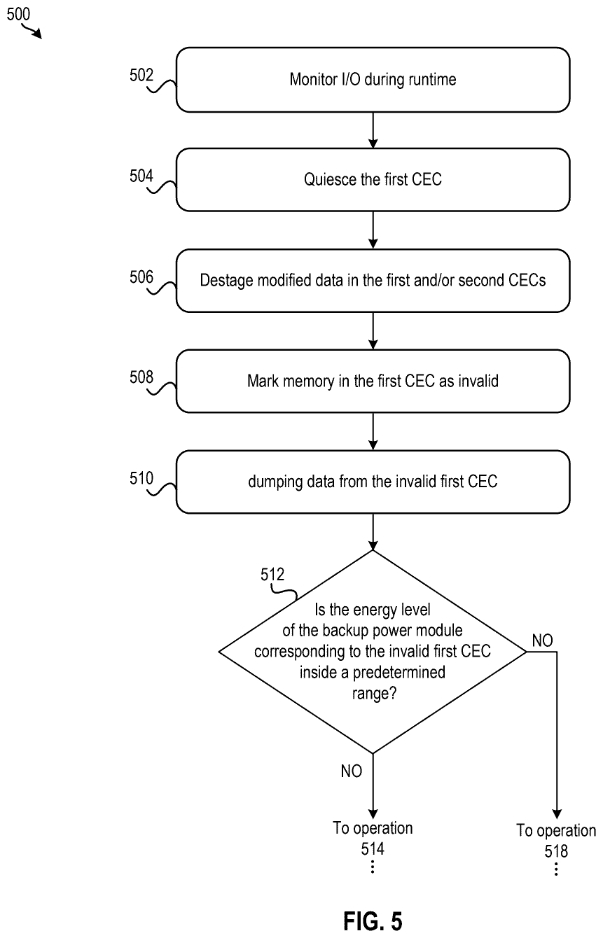

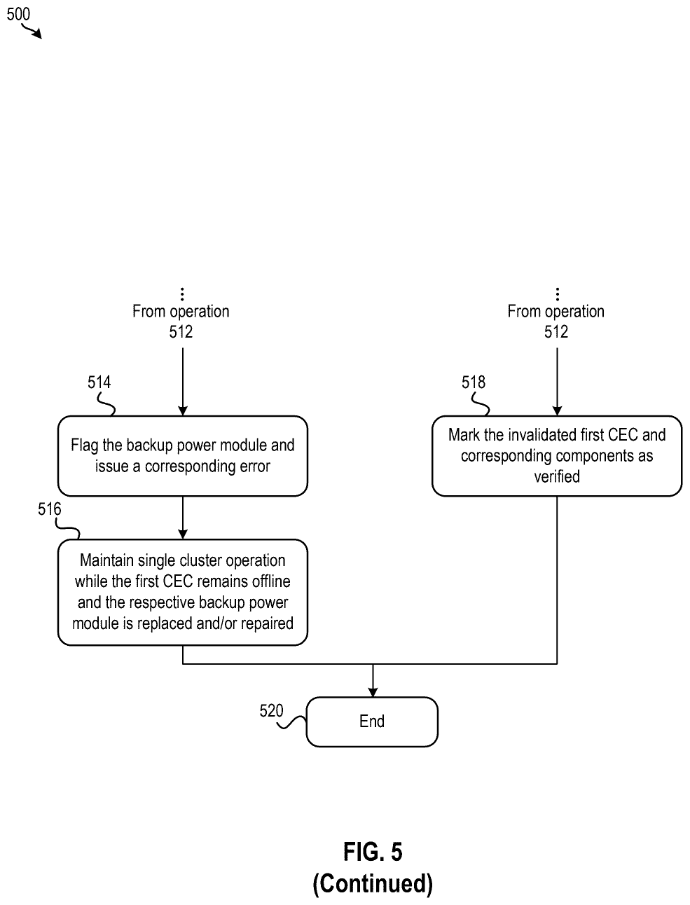

The alert preferably instructs or recommends the user to test the energy levels of the backup power modules, and take preemptive action to avoid data loss resulting from an unexpectedly depleted backup power module. For instance, the “preemptive action” may include replacing, recharging, repairing, etc. one or more of the backup power modules. Accordingly, inspecting the energy levels of the backup power modules in such instances improves overall data retention. The relative health of the battery backups may also be evaluated over time to ensure the memory operates successfully, e.g., even in response to an unexpected power loss. For instance, the energy levels of battery backups may be tested during concurrent code loads (e.g., see FIG. 5). Similarly, energy levels may be inspected during periods of low input/output (I/O) traffic, e.g., as will be described in further detail below.

Returning to operation 308, method 300 advances to operation 312 in response to determining the amount of time that has passed is in the predetermined range. In other words, method 300 advances to operation 312 in response to determining that an acceptable amount of time has passed since the backup power module(s) were intended to have been shut down (e.g., taken offline). There, operation 312 includes flagging the one or more backup power modules for inspection. In some approaches, information 312a, 312b associated with the flag may be sent to the corresponding backup power module at nodes 302 and 303, respectively. It follows that backup power modules that have been flagged may be inspected first or before other backup power modules during a subsequent low I/O period, in response to a concurrent code load, etc., as will soon become apparent.

Looking back now to operation 306, method 300 advances to operation 314 in response to determining that the memory in the system was properly disarmed during manufacture. In other words, the flowchart proceeds from operation 306 to operation 314 in response to determining memory in the system connected to backup power modules was properly disarmed at the end of a controlled shutdown during manufacture of the memory. The outcome of this determination may also be displayed (e.g., to a user). Thus, a result outlining that the memory in the system was properly disarmed during manufacture may be displayed to a client in response to proceeding to operation 314. There, operation 314 includes monitoring for opportunities to inspect the backup power modules (e.g., test the energy levels thereof) that have little to no impact on operation of the system as a whole. For example, some approaches include monitoring system throughput for periods where I/O falls outside a predetermined range, for concurrent code loads being performed, etc., that provide such opportunities.

Accordingly, node 301 is shown as receiving information (e.g., metadata, I/O rates, throughput summaries, real-time performance metrics, sensor readings, etc.) 314a, 314b from nodes 302 and 303, respectively. This received information 314a, 314b is evaluated to determine whether the backup power modules may be tested. As shown, operation 314 continues to monitor system performance, searching for one or more of the opportunities to test the backup power modules. However, in response to identifying at least one such opportunity, method 300 advances from operation 314 to operation 316. There, operation 316 includes causing energy levels of the backup power modules to be inspected and maintained. In other words, operation 316 preferably includes monitoring the energy level stored in each backup power module and ensuring the memory is configured as desired, e.g., as will be described in further detail below.

It should be noted that the term “energy level(s)” backup power modules as used herein is intended to refer to the potential energy that is stored in the backup power modules. It follows that the energy levels may be quantified (e.g., explained) using different units depending on the given approach. For example, rather than evaluating energy levels of a backup power module with respect to predetermined ranges, the potential energy stored in the backup power module may be quantified (e.g., determined) using voltage(s), current(s), power readings, etc., e.g., as would be appreciated by one skilled in the art after reading the present description.

Referring momentarily to FIG. 3B, exemplary sub-operations of causing of the energy levels of the backup power modules to be tested are illustrated in accordance with one approach. The sub-operations of FIG. 3B are described in the context of an example with memory having a first and second CEC, which is in no way intended to be limiting. It follows that one or more of these sub-operations may be used to perform operation 316 of FIG. 3A. However, it should be noted that the sub-operations of FIG. 3B are illustrated in accordance with one approach which is in no way intended to be limiting.

As shown, sub-operation 350 includes causing the first CEC in memory to be quiesced. Sub-operation 350 may thereby include sending one or more instructions that result in the on-disk data of the first CEC into a state suitable for backup. According to some examples, this process may include such operations as flushing dirty buffers from the operating system in-memory cache to disk, or other higher-level, application-specific tasks. Moreover, sub-operation 352 includes causing all modified data to be destaged from the first and second CECs in the memory.

In response to all modified data being destaged from both CECs, method 300 advances from sub-operation 352 to sub-operation 354. There, sub-operation 354 includes causing the first CEC to be invalidated. In some approaches, the first CEC may be invalidated by clearing the valid bit of one or more cache lines thereof, but the CEC may be invalidated using any procedures that would be apparent to one skilled in the art after reading the present description. In response to invalidating the first CEC, the flowchart proceeds to sub-operation 356.

There, sub-operation 356 includes causing data to be removed from the invalidated first CEC. Moreover, sub-operation 358 includes determining whether Is the energy level of the backup power module inside a predetermined range. In other words, sub-operation 358 includes causing the energy level of one of the backup power modules that are connected to the invalidated first CEC to be tested and compared against another predetermined range. In response to determining the energy level of the respective backup power module is not inside (i.e., is outside) the predetermined range, the first CEC is kept invalidated while the second CEC (which is still valid) is used to process I/Os as they occur. In other words, the second CEC maintains operation while the first CEC is kept offline in situations where the first CEC is insufficiently charged.

Accordingly, the flowchart proceeds from sub-operation 358 to sub-operation 360 where a warning is issued. The warning may convey that the backup power module connected to the invalidated first CEC is unable to reliably support performance. The warning may further outline (e.g., explain) that the first CEC will remain invalidated while the corresponding backup power module is insufficiently charged. In other words, the warning may indicate that the first CEC remains invalidated, and the second CEC will satisfy I/Os until the backup power module and/or memory as a whole can be repaired and/or replaced. The warning may be issued to a user associated with the first and/or second CECs (e.g., an administrator), a client using the CECs to satisfy I/Os, etc.

Proceeding to sub-operation 362, where the invalidated first CEC is returned to an intended state. In other words, the backup power module is replaced, recharged, repaired, etc., such that it stores a sufficient (e.g., desired) energy level to protect against data loss. It follows that the system remains in a single CEC mode while the invalidated first CEC is returned to an intended state. Meanwhile, the second CEC is still active and is used to satisfy I/Os, maintaining throughput while the drained backup power module is repaired. Accordingly, inspecting the energy levels of the backup power modules in such instances improves overall data retention.

In response to determining that the first CEC has been returned to an intended (e.g., repaired, recharged, replaced, etc.) the flowchart proceeds from sub-operation 362 to sub-operation 364. There, sub-operation 364 includes causing the repaired first CEC to be revalidated. It should also be noted that the flowchart proceeds directly from sub-operation 358 to sub-operation 364 in response to determining the energy level of the respective backup power module is inside the predetermined range.

From sub-operation 364, the flowchart proceeds to sub-operation 366. There, sub-operation 366 includes causing the second CEC to be quiesced. It follows that performing sub-operation 366 may implement the same or similar approaches as performing sub-operation 350 above. For instance, one or more instructions may be sent to a client location, resulting in the second CEC being quiesced.

From sub-operation 366, the flowchart proceeds to sub-operation 368. There, sub-operation 368 includes causing all modified data to be destaged from the first CEC as well as the second CEC. In response to all modified data being destaged from both CECs, method 300 advances from sub-operation 368 to sub-operation 370. There, sub-operation 370 includes causing the second CEC to be invalidated. In some approaches, the second CEC may be invalidated by clearing the valid bit of one or more cache lines thereof, but the CEC may be invalidated using any procedures that would be apparent to one skilled in the art after reading the present description. In response to invalidating the second CEC, the flowchart proceeds to sub-operation 372.

There, sub-operation 372 includes causing all data to be removed from the invalidated second CEC. Moreover, sub-operation 374 includes causing the energy level of the backup power modules that are connected to the invalidated second CEC to be tested and compared against another predetermined range. In response to determining the energy level of the respective backup power module is not inside (i.e., is outside) the predetermined range, the flowchart proceeds from sub-operation 374 to sub-operation 376 where a warning is issued. The warning preferably conveys that the backup power module connected to the invalidated second CEC is unable to reliably support performance. The warning may further outline (e.g., explain) that the second CEC will remain invalidated while the corresponding backup power module is insufficiently charged. In other words, the warning may indicate that the second CEC remains invalidated, and the first CEC will satisfy I/Os until the backup power module and/or memory as a whole can be repaired and/or replaced. The warning may be issued to a user associated with the first and/or second CECs (e.g., an administrator), a client using the CECs to satisfy I/Os, etc.

Proceeding further to sub-operation 378, the second CEC is kept invalidated while the first CEC (which has been revalidated) is used to process I/Os as they occur. In other words, the first CEC maintains operation while the second CEC is kept offline in situations where the second CEC is insufficiently charged. The invalidated second CEC is also returned to an intended state. In other words, the backup power module is replaced, recharged, repaired, etc., such that it stores a sufficient (e.g., desired) energy level to protect against data loss. Again, it follows that the system remains in a single CEC mode while the invalidated first CEC is returned to an intended state. Inspecting the energy levels of the backup power modules in such instances improves overall data retention. Moreover, in response to determining that the second CEC has been returned to an intended (e.g., repaired, recharged, replaced, etc.) the flowchart proceeds from sub-operation 378 to sub-operation 380. There, sub-operation 380 includes causing the second CEC to be revalidated.

The relative health of the battery backups may also be evaluated over time to ensure the memory operates successfully, e.g., even in response to an unexpected power loss. For instance, the energy levels of battery backups may be tested during concurrent code loads (e.g., see FIG. 5 below). Similarly, energy levels may be inspected during periods of low input/output (I/O) traffic, e.g., as will be described in further detail below.

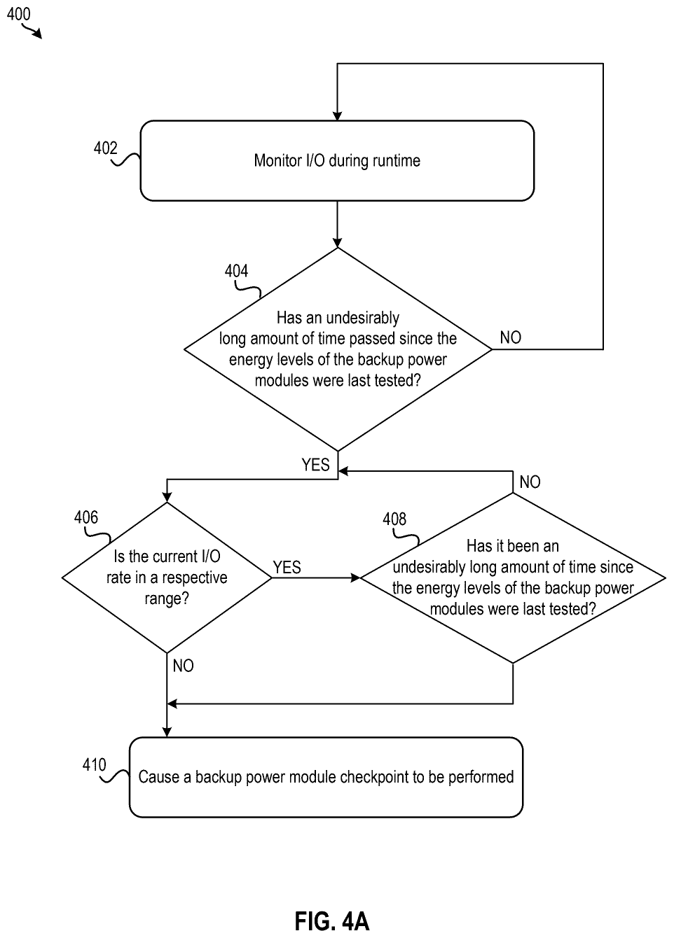

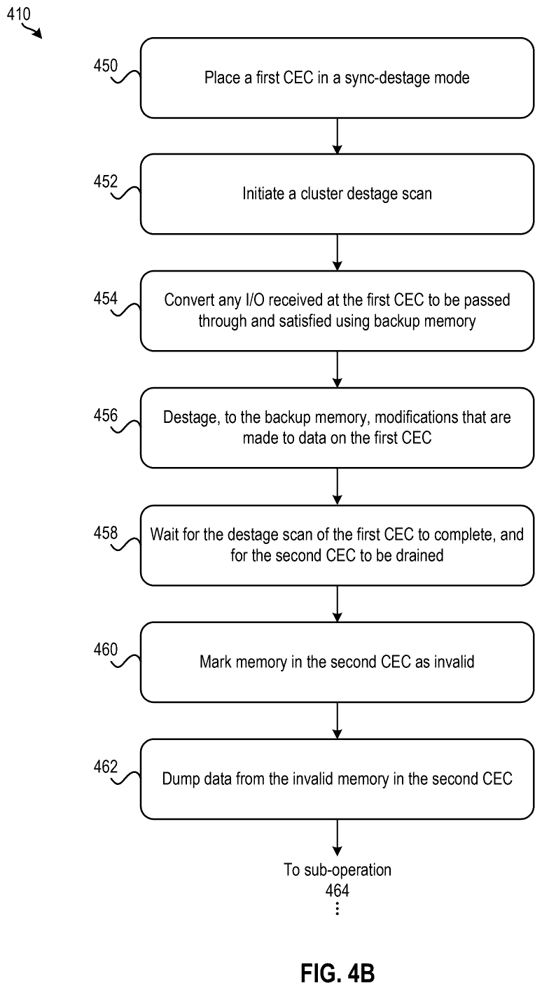

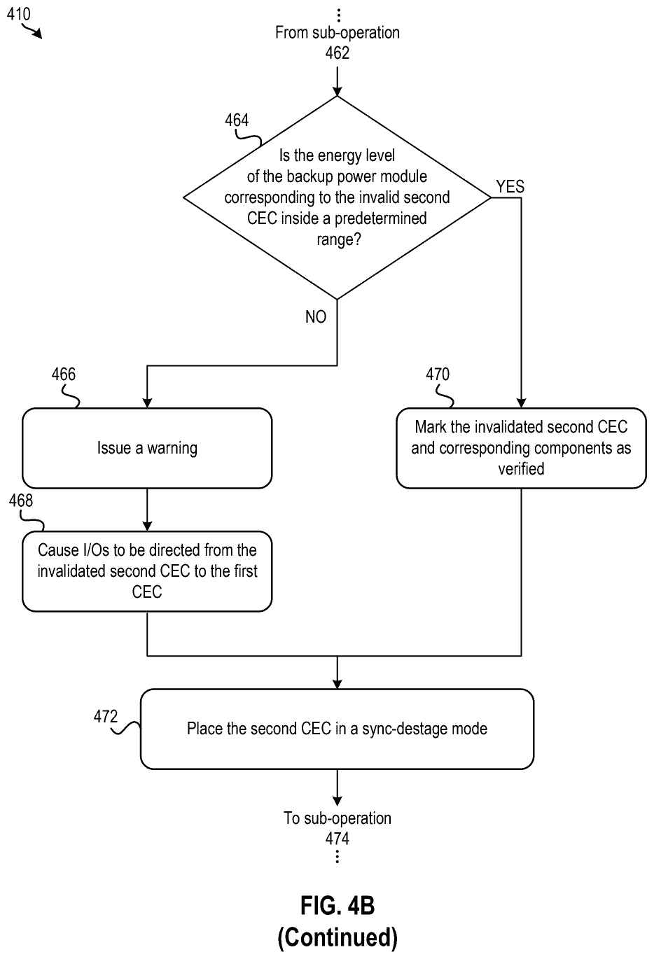

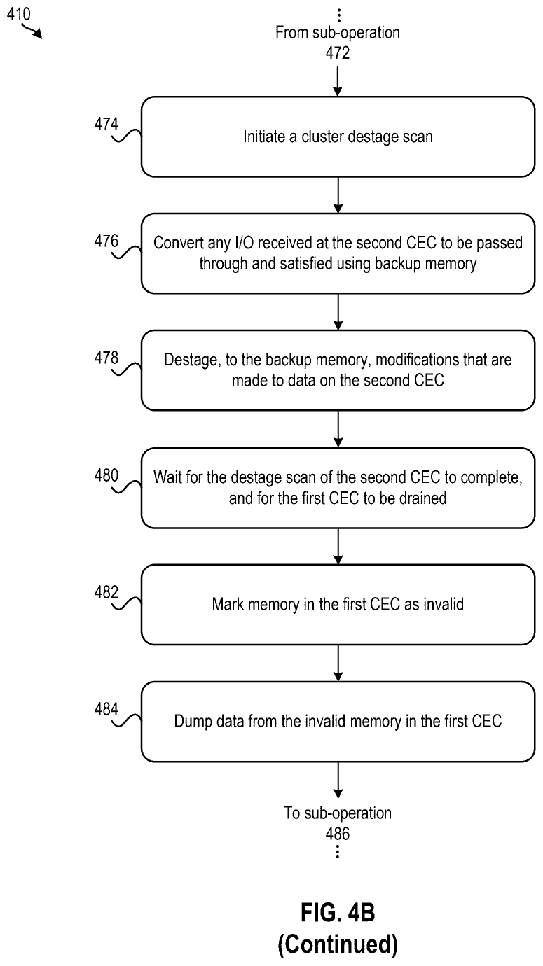

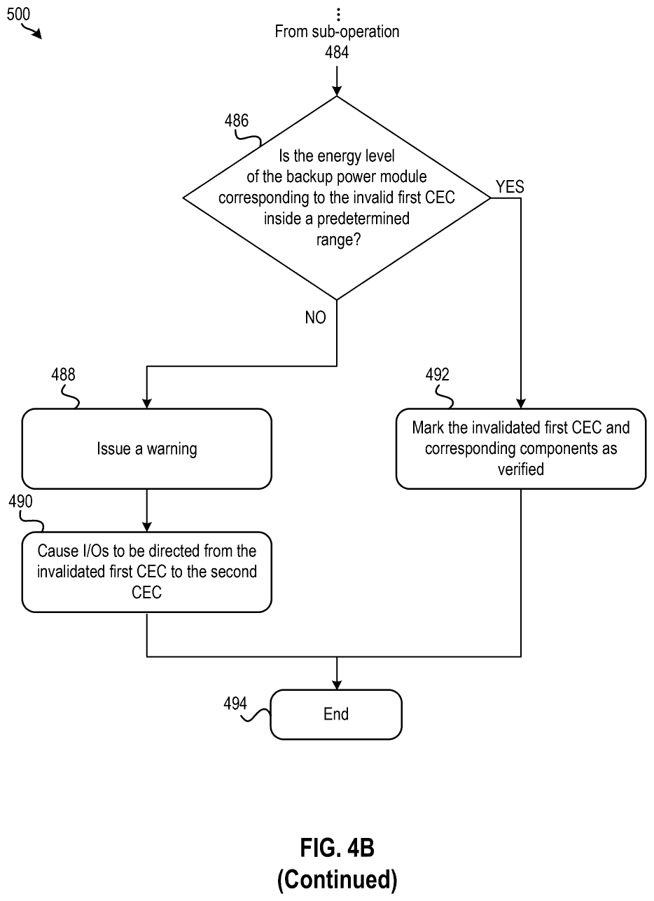

Looking now to FIG. 4A, a flowchart of a method 400 for monitoring memory performance over time is illustrated in accordance with one approach. The method 400 may be performed in accordance with the present invention in any of the environments depicted in FIGS. 1-3B, among others, in various approaches. Of course, more or less operations than those specifically described in FIG. 4A may be included in method 400, as would be understood by one of skill in the art upon reading the present descriptions.

Each of the steps of the method 400 may be performed by any suitable component of the operating environment using known techniques and/or techniques that would become readily apparent to one skilled in the art upon reading the present disclosure. For example, in various approaches, the method 400 may be partially or entirely performed by a controller, a processor, etc., or some other device having one or more processors therein. The processor, e.g., processing circuit(s), chip(s), and/or module(s) implemented in hardware and/or software, and preferably having at least one hardware component may be utilized in any device to perform one or more steps of the method 400. Illustrative processors include, but are not limited to, a central processing unit (CPU), an application specific integrated circuit (ASIC), a field programmable gate array (FPGA), etc., combinations thereof, or any other suitable computing device known in the art.

As shown in FIG. 4A, operation 402 includes monitoring I/O during runtime. In some approaches, operation 402 includes monitoring interval counters for I/O activity during runtime. Monitoring the I/O activity allows for approaches herein to determine how long it has been since backup power modules have been tested. Accordingly, operation 404 includes determining how long it has been since the energy levels of the backup power modules were last tested.

Proceeding to operation 404, a determination is made as to whether an undesirably long amount of time has passed since the energy levels of the backup power modules were last tested. Operation 404 may compare the amount of time to one or more predetermined ranges. In other approaches, a user may be prompted to provide a desired amount of time.

In response to determining the energy levels of the backup power modules were tested (e.g., inspected) recently, method 400 is shown as returning to operation 402. This allows for performance to continue to be monitored. However, method 400 advances from operation 404 to operation 406 in response to determining an undesirable amount of time has passed since the energy levels of the backup power modules were last tested. There, operation 406 includes monitoring the current I/O rate and determining whether it is in a respective range. While the active I/O rate remains in the respective range, method 400 is shown as advancing from operation 406 to operation 408. There, operation 408 includes determining whether it has been an undesirably long time since the energy levels of the backup power modules were last tested. In other words, although the current I/O rate may not be ideal (e.g., favorable) to test the backup power modules without impacting system performance, it is also preferred that the backup power modules do not go unchecked for long periods of time. The preferred maximum time between energy level checks may be determined during the manufacture process based on the number, type, configuration, etc. of the backup power modules, industry standards, client specifications, etc. Moreover, the amount of time permitted between energy level checks may dynamically shift as the current I/O rate fluctuates over time. As a result, the chance of experiencing data loss is significantly reduced, e.g., as would be appreciated by one skilled in the art after reading the present description.

However, in response to determining that it has been an undesirably long time since the energy levels of the backup power modules were last tested, method 300 advances from operation 408 to operation 410, despite the current high I/O rates determined in operation 406. Method 400 also advances to operation 410 from operation 406 in response to determining that the current I/O rate is outside the respective range. There, operation 410 includes causing a backup power module checkpoint to be performed. The backup power module checkpoint is preferably performed to test the energy levels of one or more backup power modules that are implemented in memory. Thus, method 400 may proceed differently based on the outcome of the backup power module checkpoint, e.g., as will be described in further detail below.

Referring momentarily to FIG. 4B, exemplary sub-operations of causing a backup power module checkpoint to be performed are illustrated in accordance with one approach. The sub-operations of FIG. 4B are described in the context of an example with memory having a first and second CEC, which is in no way intended to be limiting. It follows that one or more of these sub-operations may be used to perform operation 410 of FIG. 4A. However, it should be noted that the sub-operations of FIG. 4B are illustrated in accordance with one approach which is in no way intended to be limiting.

As shown, sub-operation 450 includes placing a first CEC in a sync-destage (e.g., write through) mode. On a first iteration of the sub-operations in FIG. 4B, the CEC being evaluated may be the “first CEC.” Subsequent performances of the sub-operations involve other CECs. For instance, a second iteration involves evaluating the “second CEC.” It follows that the sub-operations in FIG. 4B may be repeated in an iterative fashion for each CEC in a system having the backup power modules being evaluated. In some approaches, sub-operation 450 may involve setting a flag before calling a predetermined (e.g., pre-programmed) subroutine configured to inspect each of the CECs in memory. Accordingly, the flowchart proceeds to sub-operation 452 where a cluster destage scan is initiated. This cluster destage scan works to destage data in the respective CEC being evaluated. Accordingly, sub-operation 452 may include initiating a destage scanning of the first CEC, e.g., as would be appreciated by one skilled in the art after reading the present description. The destage scan may be initiated as a result of sending one or more instructions, commands, requests, etc.

The destage scan also allows for memory in the other (second) CEC to be drained. Accordingly, sub-operation 452 involves draining the non-volatile memory in the second CEC, and marking the drained second CEC as currently invalid. From sub-operation 452, method 400 advances to sub-operation 454. There, sub-operation 454 includes converting any I/O received at the first CEC to be passed through and satisfied using backup memory. For example, persistent memory (e.g., such as hard disk drives, magnetic tape, optical media, etc.) may be used to satisfy I/Os while one or more of the CECs are currently invalid and/or destaged. Moreover, a warning may be produced in response to all data (e.g., tracks) being destaged from the respective CECs to the backup memory.

Proceeding now from sub-operation 454 to sub-operation 456, it should be noted that any modifications that are made to data (e.g., metadata tracks) on the respective CEC are destaged to the backup memory. In other words, it is preferred that journal entries are not added to the second CEC in response to modifications that are received for data in the first CEC. Rather, the modified data is destaged to the backup memory (e.g., HDD) in response to the modifications received in sub-operation 456 being processed.

From sub-operation 456, the flowchart proceeds to sub-operation 458. There, sub-operation 458 includes waiting for the destage scan of the first CEC to complete, and waiting for the second CEC to be completed drained. In response to determining that the destage scan of the first CEC has completed, and that the second CEC has been drained, the flowchart is shown as proceeding to sub-operation 460. There, sub-operation 460 includes marking memory in the second CEC as invalid. In other words, sub-operation 460 involves marking the memory (e.g., persistent random-access memory) in the second CEC as invalid.

Furthermore, sub-operation 462 includes dumping data from the invalid memory in the second CEC. This desirably allows for the energy level of a backup power module connected to the second CEC to be tested. Accordingly, sub-operation 464 includes testing the energy level of the backup power module corresponding to the invalid second CEC. In preferred approaches, sub-operation 462 determines whether the energy level of the backup power module connected to the second CEC is inside a predetermined range. For instance, in some approaches the energy level of the backup power module is compared to a range that has been predetermined by a user, based on industry standards, dynamically generated based at least in part on past performance, etc.

As shown, the flowchart proceeds from sub-operation 464 to sub-operation 466 in response to determining the energy level of the backup power module connected to the second CEC is not inside (e.g., outside) the predetermined range. There, sub-operation 466 includes issuing a warning. The warning preferably conveys the backup power module connected to the second CEC is unable to reliably support performance. The warning may outline (e.g., explain) that the second CEC will remain invalidated so long as the corresponding backup power module is insufficiently charged. In other words, the warning may indicate that the second CEC is to remain invalidated, while the first CEC is used to satisfy I/Os, e.g., until the backup power module and/or memory as a whole can be repaired and/or replaced. The warning may be issued to a user associated with the first and/or second CEC s (e.g., an administrator), a client using the CECs to satisfy I/Os, etc.

Accordingly, sub-operation 468 includes causing I/Os to be directed from the invalidated second CEC to the first CEC, at least while the backup power module is being repaired and/or replaced. It follows that in some approaches, sub-operation 468 includes switching the first CEC back from the sync-destage (e.g., write through) mode to a nominal non-volatile storage write mode. In other words, a failover to the first CEC may be established, keeping the system in a single cluster configuration while the depleted backup power module is being repaired and/or replaced.

Referring still to FIG. 4B, the flowchart is shown as advancing from sub-operation 464 to sub-operation 470 in response to determining that the backup power module corresponding to the second CEC is sufficiently charged. There, sub-operation 470 includes marking the (currently) invalidated second CEC and corresponding components (e.g., memory, backup power module, etc.) as verified. In other words, the CEC associated with the backup power module being tested may be verified as having a sufficient (e.g., intended) energy level. It follows that in some approaches, sub-operation 470 involves switching the original CEC from the sync-destage (e.g., write through) mode to a nominal mode (e.g., at least temporarily).

From sub-operation 470, the flowchart is shown as advancing to sub-operation 472. Similarly, the flowchart proceeds from sub-operation 468 to sub-operation 472. There, sub-operation 472 includes placing the second CEC in a sync-destage (e.g., write through) mode. Accordingly, sub-operation 472 may include any of the approaches described above with respect to sub-operation 450. From sub-operation 472, the flowchart proceeds to sub-operation 474 where a cluster destage scan is initiated, working to destage data in the second CEC. Accordingly, sub-operation 474 may include initiating a destage scanning of the second CEC, e.g., as described above.

The destage scan of the second CEC allows for memory in the first CEC to be drained. In other words, performing a cluster destage scan on a first CEC causes everything therein to be destaged, in addition to the opposite CEC being drained. Accordingly, sub-operation 474 may involve draining the non-volatile memory in the first CEC, and marking the drained first CEC as currently invalid. From sub-operation 474, method 400 advances to sub-operation 476 where any I/O received at the second CEC are converted to be passed through and satisfied using backup memory. Again, backup memory (e.g., such as hard disk drives, magnetic tape, optical media, etc.) may be used to satisfy I/Os while one or more of the CECs are currently invalid and/or destaged. In some approaches, a host is informed a write operation is complete in response to the respective tracks being destaged to disk (e.g., HDD). Moreover, new modifications to metadata tracks will not acquire a track identification in the opposite CEC. Thus, modified metadata tracks will be destaged to disk in response to track access ending.

Proceeding now from sub-operation 476 to sub-operation 478, it should be noted that any modifications that are made to data (e.g., metadata tracks) on the second CEC are destaged to the backup memory. In other words, it is preferred that journal entries are not added to the first CEC in response to modifications that are received for data in the second CEC. Rather, the modified data is destaged to the backup memory (e.g., HDD) in response to the modifications received in sub-operation 476 being processed.

Sub-operation 480 involves waiting for the destage scan of the second CEC to complete, and for the first CEC to be drained. In response to determining that the destage scan of the second CEC has completed, and that the first CEC has been drained (see sub-operation 480), the flowchart is shown as proceeding to sub-operation 482. There, sub-operation 482 includes marking memory in the first CEC as invalid. In other words, sub-operation 482 involves marking the memory (e.g., persistent random-access memory) in the first CEC as currently disabled. Moreover, sub-operation 484 includes dumping data from the invalidated memory in the first CEC. Furthermore, sub-operation 486 inspects and evaluates the energy level stored in the backup power module corresponding to the first CEC is inside a predetermined range. In some approaches, the predetermined range is the same as that used in sub-operation 464. In other approaches, each CEC may be assigned a respective predetermined range to apply while evaluating the energy level of the corresponding backup power module. In still other approaches, the predetermined range may be selected based on the current I/O rate, the number of backlogged requests, etc.

The flowchart proceeds from sub-operation 486 to sub-operation 488 in response to determining the energy level of the backup power module connected to the first CEC is not inside (e.g., outside) the predetermined range. There, sub-operation 488 includes issuing a warning that conveys the backup power module connected to the first CEC is unable to reliably support performance. The warning may outline (e.g., explain) that the first CEC will remain invalidated so long as the corresponding backup power module is insufficiently charged. In other words, the warning may indicate that the first CEC is to remain invalidated, while the second CEC is used to satisfy I/Os, e.g., until the backup power module and/or memory as a whole can be repaired and/or replaced. The warning may be issued to a user associated with the first and/or second CECs (e.g., an administrator), a client using the CECs to satisfy I/Os, etc.

Accordingly, sub-operation 490 includes causing I/Os to be directed from the invalidated first CEC to the second CEC. It follows that in some approaches, sub-operation 490 includes switching the second CEC back from the sync-destage (e.g., write through) mode to a nominal non-volatile storage write mode. In other words, a failover to the second CEC may be established, keeping the system in a single cluster configuration while the depleted backup power module is being repaired and/or replaced. However, sub-operation 486 advances to sub-operation 492 in response to determining that the backup power module corresponding to the first CEC is sufficiently charged. There, sub-operation 492 includes marking the first CEC and corresponding components (e.g., memory, backup power module, etc.) as verified. It follows that in some approaches, sub-operation 492 involves switching the first CEC from the sync-destage (e.g., write through) mode to a nominal mode as well.

Moreover, the system may remain in the normal operating mode as a result of testing and determining that each backup power module is sufficiently charged. In other words, the backup power module checkpoint is successfully passed in response to determining each backup power module includes a desired energy level. Accordingly, the flowchart of FIG. 4B may end upon reaching sub-operation 494. However, while the present approach has been described in the context of a system that includes two CECs, the sub-operations in FIG. 4B may be repeated any desired number of times to test the energy levels of backup power modules coupled to any number of CECs.

Returning back now to FIG. 4A, operation 410 of method 400 again includes causing a backup power module checkpoint to be performed. The backup power module checkpoint is preferably performed to test the energy levels of one or more backup power modules that are implemented in memory. Moreover, by repairing and/or replacing backup power modules identified as having insufficient energy levels, the backup power module checkpoint is desirably able to maintain data retention even during unexpected power loss.

Referring now to FIG. 5, a flowchart of a method 500 that involves monitoring for, and responding to, concurrent code loads is illustrated in accordance with one approach. The method 500 may be performed in accordance with the present invention in any of the environments depicted in FIGS. 1-4B, among others, in various approaches. Of course, more or less operations than those specifically described in FIG. 5 may be included in method 500, as would be understood by one of skill in the art upon reading the present descriptions.

Each of the steps of the method 500 may be performed by any suitable component of the operating environment using known techniques and/or techniques that would become readily apparent to one skilled in the art upon reading the present disclosure. For example, in various approaches, the method 500 may be partially or entirely performed by a controller, a processor, etc., or some other device having one or more processors therein. The processor, e.g., processing circuit(s), chip(s), and/or module(s) implemented in hardware and/or software, and preferably having at least one hardware component may be utilized in any device to perform one or more steps of the method 500. Illustrative processors include, but are not limited to, a central processing unit (CPU), an application specific integrated circuit (ASIC), a field programmable gate array (FPGA), etc., combinations thereof, or any other suitable computing device known in the art.

As shown in FIG. 5, operation 502 includes monitoring I/O during runtime. In response to identifying a concurrent code load and/or service event in the I/O, method 500 advances to operation 504. In other words, operation 502 includes monitoring the I/Os for any concurrent code loads. There, operation 504 includes quiescing the first CEC, while operation 506 includes destaging modified data in the first and/or second CECs. In some approaches, the modified data in the first and/or second CECs may be destaged as part of the quiesce process, e.g., as would be appreciated by one skilled in the art after reading the present description.

In response to destaging the modified data from both the first and second CECs, method 500 advances from operation 506 to operation 508. There, operation 508 includes marking memory in the first CEC as invalid, while operation 510 includes dumping data from memory in the invalid first CEC. As noted above, operation 510 involves clearing any valid data from the first CEC in order to safely test the respective backup power module. Accordingly, method 500 advances from operation 510 to operation 512 in response to the data being cleared.

There, operation 512 includes determining whether the backup power module corresponding to the invalid first CEC includes an energy level that is in a predetermined range. In other words, operation 512 determines whether the backup power module corresponding to the invalid first CEC is sufficiently charged. In response to determining the respective backup power module is insufficiently charged, method 500 advances to operation 514. There, operation 514 includes flagging the backup power module and issuing a corresponding error. The error preferably identifies the current electrical charge stored in the backup power module. The error may also include predicted runtimes based on projected use, recommended steps to repair and/or replace the backup power module in question, etc. Moreover, operation 516 includes maintaining single cluster operation while the first CEC remains offline, and the respective backup power module is replaced and/or repaired.

Method 500 alternatively proceeds to operation 518 from operation 512 in response to determining the respective backup power module is sufficiently charged. There, operation 518 includes marking the memory associated with the first CEC as verified. Operation 518 also preferably includes causing the first CEC to resume operation (e.g., be revalidated).

From operation 516 or operation 518, the flowchart of FIG. 5 proceeds to operation 520, whereby method 500 may end. However, it should be noted that although method 500 may end upon reaching operation 520, any one or more of the processes included in method 500 may be repeated in order to evaluate the energy level of other backup power modules. In other words, any one or more operations in FIG. 5 may be repeated for different backup power modules. In other words, method 500 may be repeated any desired number of times to evaluate any desired number of backup power modules. However, in some approaches each iteration of method 500 is performed in response to detection of a respective concurrent code load and/or service event, e.g., as would be appreciated by one skilled in the art after reading the present description.

It follows that approaches herein are desirably able to selectively inspect backup power modules during specific opportunities (e.g., during concurrent code loads, low I/O rates, etc.). While memory of a given CEC has no modified data, the memory is dumped and destaged. Moreover, in situations where energy levels are undesirably low, approaches herein are able to operate in a single CEC configuration until the backup power modules are replaced and/or repaired.

It will be clear that the various features of the foregoing systems and/or methodologies may be combined in any way, creating a plurality of combinations from the descriptions presented above.

It will be further appreciated that approaches of the present invention may be provided in the form of a service deployed on behalf of a customer to offer service on demand.

The descriptions of the various approaches of the present invention have been presented for purposes of illustration, but are not intended to be exhaustive or limited to the approaches disclosed. Many modifications and variations will be apparent to those of ordinary skill in the art without departing from the scope and spirit of the described approaches. The terminology used herein was chosen to best explain the principles of the approaches, the practical application or technical improvement over technologies found in the marketplace, or to enable others of ordinary skill in the art to understand the approaches disclosed herein.

What is claimed is:

1. A computer-implemented method (CIM), comprising:
in response to a system detecting an initial microcode load, determining whether memory in the system was disarmed during manufacture, wherein the memory is connected to backup power modules;
in response to determining that the memory was disarmed during manufacture, monitoring for concurrent code loads;
in response to detecting a concurrent code load, causing energy levels of the backup power modules to be tested; and
in response to determining the energy levels of one or more of the backup power modules are outside a predetermined range, issuing a warning.

2. The CIM of claim 1, wherein the causing of the energy levels of the backup power modules to be tested includes:
causing a first Central Electronic Complex (CEC) in the memory to be quiesced;
causing modified data to be destaged from the first CEC and a second CEC in the memory;
causing the first CEC to be invalidated;
causing data to be removed from the first CEC; and
causing the energy level of a respective one of the backup power modules that is connected to the first CEC to be tested.

3. The CIM of claim 2, wherein the causing of the energy levels of the backup power modules to be tested further includes:
in response to determining the energy level of the respective backup power module is outside the predetermined range, causing all the second CEC to process inputs/outputs (I/Os),
wherein the warning outlines that the first CEC will remain invalidated.

4. The CIM of claim 3, wherein the causing of the energy levels of the backup power modules to be tested further includes:
in response to determining that the first CEC has been repaired, causing the first CEC to be revalidated.

5. The CIM of claim 2, wherein the causing of the energy levels of the backup power modules to be tested further includes:
in response to determining the energy level of the respective backup power module is inside the predetermined range, causing the first CEC to be revalidated;
causing the second CEC to be quiesced;
causing the second CEC to be invalidated;
causing data to be removed from the second CEC; and
causing the energy level of a respective one of the backup power modules that is connected to the second CEC to be tested.

6. The CIM of claim 1, further comprising:
determining a current I/O rate; and
in response to determining the current I/O rate is outside a second predetermined range, causing a backup power module checkpoint to be performed.

7. The CIM of claim 6, wherein the causing of the backup power module checkpoint to be performed includes:
causing a destage scan to be performed on a first Central Electronic Complex (CEC) in the memory;
causing non-volatile memory in a second CEC to be drained;
causing the energy level of a respective one of the backup power modules that is connected to the second CEC to be tested; and
in response to determining the energy level of the backup power module that is connected to the second CEC is outside the predetermined range, causing I/Os to be directed to the first CEC.

8. The CIM of claim 7, wherein the causing of the backup power module checkpoint to be performed further includes:
in response to determining the energy level of the backup power module that is connected to the second CEC is inside the predetermined range, causing a destage scan to be performed on the second CEC;
causing non-volatile memory in the first CEC to be drained;
causing the energy level of a respective one of the backup power modules that is connected to the first CEC to be tested; and
in response to determining the energy level of the backup power module that is connected to the first CEC is inside the predetermined range, concluding the backup power module checkpoint successfully passed.

9. The CIM of claim 1, further comprising:
in response to determining that the memory was not disarmed during manufacture, determining whether an amount of time between (i) a controlled shutdown during manufacture, and (ii) the system experiencing the initial microcode load, is in a second predetermined range; and
in response to determining the amount of time is not in the second predetermined range, causing an alert to be displayed to a user, the alert instructing the user to test the energy levels of the backup power modules.

10. The CIM of claim 1, wherein the memory includes at least one non-volatile dual in-line memory module (NVDIMM).

11. A computer program product (CPP), comprising:
a set of one or more computer-readable storage media; and
program instructions, collectively stored in the set of one or more storage media, for causing a processor set to perform the following computer operations:
in response to a system experiencing an initial microcode load, determine whether memory in the system was disarmed during manufacture, wherein the memory is connected to backup power modules;
in response to determining that the memory was disarmed during manufacture, monitor for concurrent code loads;
in response to detecting a concurrent code load, cause energy levels of the backup power modules to be tested; and
in response to determining the energy levels of one or more of the backup power modules are outside a predetermined range, issue a warning.

12. The CPP of claim 11, wherein the causing of the energy levels of the backup power modules to be tested includes:
causing a first Central Electronic Complex (CEC) in the memory to be quiesced;
causing modified data to be destaged from the first CEC and a second CEC in the memory;
causing the first CEC to be invalidated;
causing data to be removed from the first CEC; and
causing the energy level of a respective one of the backup power modules that is connected to the first CEC to be tested.

13. The CPP of claim 12, wherein the causing of the energy levels of the backup power modules to be tested further includes:
in response to determining the energy level of the respective backup power module is outside the predetermined range, causing all the second CEC to process inputs/outputs (I/Os),
wherein the warning outlines that the first CEC will remain invalidated.

14. The CPP of claim 13, wherein the causing of the energy levels of the backup power modules to be tested further includes:
in response to determining that the first CEC has been repaired, causing the first CEC to be revalidated.

15. The CPP of claim 12, wherein the causing of the energy levels of the backup power modules to be tested further includes:
in response to determining the energy level of the respective backup power module is inside the predetermined range, causing the first CEC to be revalidated;
causing the second CEC to be quiesced;
causing the second CEC to be invalidated;
causing data to be removed from the second CEC; and
causing the energy level of a respective one of the backup power modules that is connected to the second CEC to be tested.
determining a current I/O rate; and
in response to determining the current I/O rate is outside a second predetermined range, causing a backup power module checkpoint to be performed.

16. The CPP of claim 15, wherein the causing of the backup power module checkpoint to be performed includes:
causing a destage scan to be performed on a first Central Electronic Complex (CEC) in the memory;
causing non-volatile memory in a second CEC to be drained;
causing the energy level of a respective one of the backup power modules that is connected to the second CEC to be tested; and
in response to determining the energy level of the backup power module that is connected to the second CEC is outside the predetermined range, causing I/Os to be directed to the first CEC.

17. The CPP of claim 16, wherein the causing of the backup power module checkpoint to be performed further includes:
in response to determining the energy level of the backup power module that is connected to the second CEC is inside the predetermined range, causing a destage scan to be performed on the second CEC;
causing non-volatile memory in the first CEC to be drained;
causing the energy level of a respective one of the backup power modules that is connected to the first CEC to be tested; and
in response to determining the energy level of the backup power module that is connected to the first CEC is inside the predetermined range, concluding the backup power module checkpoint successfully passed.

18. The CPP of claim 11, wherein the program instructions are for causing the processor set to further perform the following computer operations:
in response to determining that the memory was not disarmed during manufacture, determine whether an amount of time between (i) a controlled shutdown during manufacture, and (ii) the system experiencing the initial microcode load, is in a second predetermined range; and
in response to determining the amount of time is not in the second predetermined range, cause an alert to be displayed to a user, the alert instructing the user to test the energy levels of the backup power modules.

19. The CPP of claim 11, wherein the memory includes at least one non-volatile dual in-line memory module (NVDIMM).

20. A computer system (CS), comprising:
a processor set;
a set of one or more computer-readable storage media;
program instructions, collectively stored in the set of one or more storage media, for causing the processor set to perform the following computer operations:
in response to a system experiencing an initial microcode load, determine whether memory in the system was disarmed during manufacture, wherein the memory is connected to backup power modules;
in response to determining that the memory was disarmed during manufacture, monitor for concurrent code loads;
in response to detecting a concurrent code load, cause energy levels of the backup power modules to be tested; and
in response to determining the energy levels of one or more of the backup power modules are outside a predetermined range, issue a warning.
